(19) United States
(12) Patent Application Publication
(10) Pub. No.: US 2020/0091020 A1
(43) Pub. Date: Mar. 19, 2020

(54) PAD STRUCTURES IN SEMICONDUCTOR DEVICES

(71) Applicant: GLOBALFOUNDRIES Singapore Pte. Ltd., Singapore (SG)

(72) Inventors: WANBING YI, Singapore (SG); LAIQIANG LUO, Singapore (SG); XINGYU CHEN, Singapore (SG); FAN ZHANG, Singapore (SG); JUAN BOON TAN, Singapore (SG)

(21) Appl. No.: 16/129,793

(22) Filed: Sep. 13, 2018

(51) Int. Cl. H01L 21/66; H01L 23/522; H01L 23/00

(52) U.S. Cl. CPC H01L 22/32; H01L 23/5226; H01L 24/05; H01L 24/03; H01L 2224/0391; H01L 2224/022; H01L 2224/05573; H01L 2224/05624; H01L 2224/05124; H01L 2224/05009

(57) ABSTRACT

A semiconductor interconnect structure including a conductive layer, a plurality of interconnect vias and a pad is presented. The interconnect vias are formed over the conductive layer and the pad having a substantially flat surface is formed over the plurality of interconnect vias. The conductive layer may be a conductive line and/or a conductive plate connected to a conductive line.

### FIELD OF THE INVENTION

The presently disclosed subject matter relates generally to structures in semiconductor devices, and more particularly to pad structures in semiconductor devices and their method of fabrication.

### BACKGROUND

Integrated circuits have progressed over the years and have become increasingly more complex in functionality, encompassing more features and operating at higher speeds than predecessor circuits. Additionally, the integrated circuits have become smaller in dimension with the use of more interconnecting structures. As the integrated circuits become denser in overall circuitry, the number of pads per integrated circuit has also increased.

There are typically two types of pads used in an integrated circuit—bond pads and probe pads. Bond pads are used to electrically connect the integrated circuit to external components, for example a printed circuit board, via wire bonding or flip-chip bonding. On the other hand, probe pads are used for testing an integrated circuit during a probe operation to assess the electrical performance of the integrated circuit, prior to dicing into individual chips. Bond pads are typically arranged on the periphery of that circuit or within the chip area based on different package solutions, whereas probe pads are typically placed within in the frame area.

The pads are typically made from a conductive material, such as aluminum (Al) and are deposited using conventional physical vapor deposition (PVD) process. The pads are generally placed away from any underlying interconnect vias as the interconnect vias will cause undesirable concave topology on pad surfaces due to the intrinsic nature of the PVD process. A concave pad surface topology will result in residual passivation layer remaining on the pad surface that cannot be effectively removed by subsequent etching and cleaning steps after a pad opening process. The typical pad has a width ranging from 40 to 50 um, and an interconnect via has a typical width of about 3 um.

The increasing complexity and diversification of applications in an integrated circuit has increased the need for electrical testing, and consequently, the corresponding number of probe pads. Probe pads must be placed within the chip area for some applications where in-die monitoring and debugging are required. However, as the probe pads are not used in the operational mode of an integrated circuit, the area taken up by the probe pads can be considered as “wasted” space, i.e., the integrated circuit being larger than what is actually required for device operation.

As described above, the conventional pad structures are not suited to effectively cope with a reduction in chip size and an increase in quantity of pads, especially when in-die monitoring is needed.

### SUMMARY

To achieve the foregoing and other aspects of the present disclosure, a probe pad-on-vias structure having a reduced size compared to conventional probe pads and a method of fabricating the same are presented.

According to an aspect of the present disclosure, a semiconductor device is provided that includes a conductive layer, a plurality of interconnect vias, and a pad. The interconnect vias are formed over the conductive layer and the pad having a substantially flat surface is formed over the plurality of interconnect vias. The conductive layer may be a conductive line and/or a conductive plate connected to a conductive line.

According to another aspect of the present disclosure, a method of fabricating a semiconductor device having a substantially flat pad over a plurality of interconnect vias on a conductive layer is provided. The method comprises providing a conductive layer and forming a dielectric layer over the conductive layer. A plurality of via openings is formed in the dielectic layer over the conductive layer. The conductive layer may be a conductive line and/or a conductive plate connected to a conductive line. A conductive material is deposited in the via openings and over the dielectric layer to form interconnect vias and a pad having substantially flat surface.

### BRIEF DESCRIPTION OF THE DRAWINGS

The embodiments of the present disclosure will be better understood from a reading of the following detailed description, taken in conjunction with the accompanying drawings:

FIGS. 1A-1D are cross-sectional views of a semiconductor device, according to embodiments of the disclosure, depicting the formation of a reduced-size probe pad-on-vias structure with a substantially flat pad surface over a conductive layer.

FIG. 2 is a cross-sectional view of a semiconductor device, according to another embodiment of the disclosure.

FIG. 3 is a cross-sectional view of a semiconductor device, according to yet another embodiment of the disclosure.

FIG. 4 is a top view of a semiconductor device, according to a further embodiment of the disclosure.

FIG. 5 is a cross-sectional view of a semiconductor device, according to another further embodiment of the disclosure.

FIG. 6 is a cross-sectional view of a semiconductor device, according to a yet further embodiment of the disclosure.

For simplicity and clarity of illustration, the drawings illustrate the general manner of construction, and certain descriptions and details of well-known features and techniques may be omitted to avoid unnecessarily obscuring the discussion of the described embodiments of the disclosure. In the present disclosure, the semiconductor device has structures beneath the conductive layer that are not shown.

Additionally, elements in the drawings are not necessarily drawn to scale. For example, the dimensions of some of the elements in the drawings may be exaggerated relative to other elements to help improve understanding of embodiments of the disclosure. The same reference numerals in different drawings denote the same elements, while similar reference numerals may, but do not necessarily, denote similar elements.

### DETAILED DESCRIPTION

The following detailed description is exemplary in nature and is not intended to limit the device or the application and uses of the device. Furthermore, there is no intention to be bound by any theory presented in the preceding background of the device or the following detailed description.

In order to minimize chip area used for electrical testing purposes, a reduced-size probe pad-on-vias structure with a substantially flat pad surface and a method of fabricating the same are presented. The smaller sized probe pad enables placements of more probe pads within the chip area and/or frame area, and also enables pad formations on top of the interconnects vias without an undesirable concave topology. The substantially flat pad surface will enable effective removal of residual passivation material from the pad surface after a pad opening process. As measurements of electrical tests are largely influenced by contact resistance between a probe tip and the pad surface, any residual passivation material on the pad surface will lead to poor contact with the probe tip and affect electrical data.

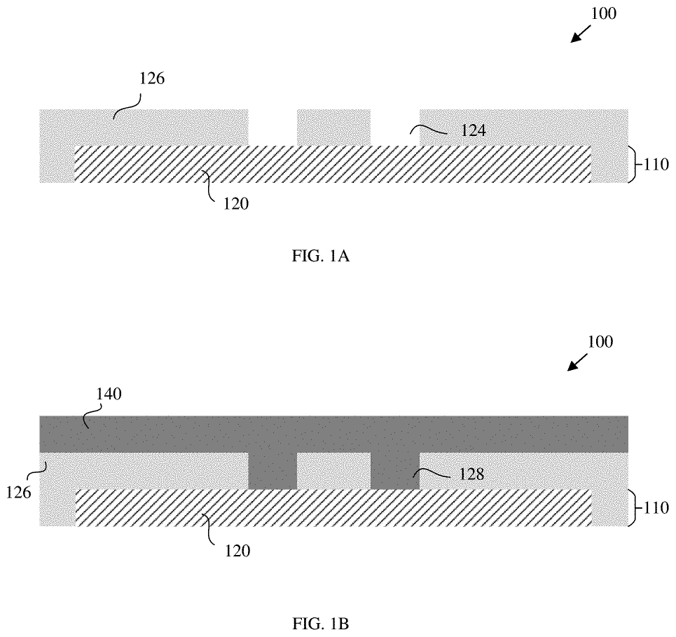

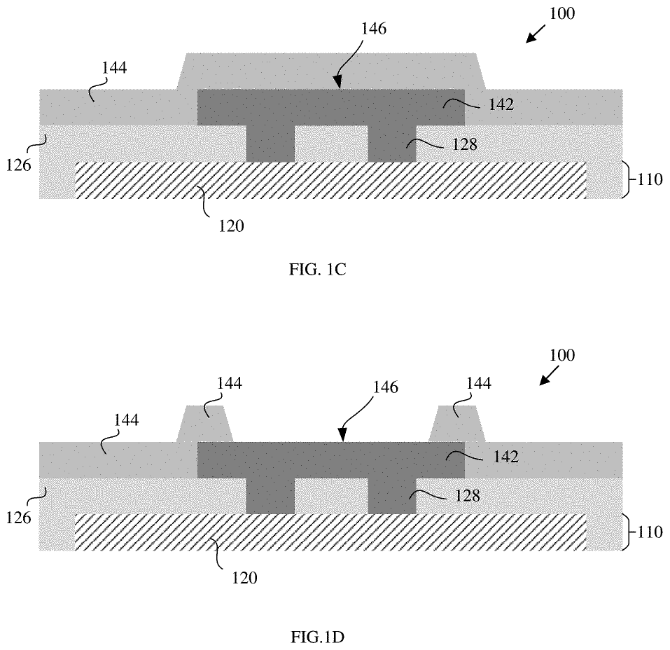

FIGS. 1A-1D are cross-sectional views of a top section of a semiconductor device 100, in accordance with embodiments of the disclosure. FIGS. 1A-1D illustrate the present method for fabricating a reduced-size probe pad-on-via structure with a substantially flat pad surface over a conductive layer. The conductive layer may be a conductive line and/or a conductive plate connected to a conductive line.

FIG. 1A is a cross-sectional view of the semiconductor device 100 having via openings 124 formed over a conductive layer 110, according to an embodiment of the disclosure. Specifically in FIG. 1A, the conductive layer 110 includes a conductive line 120 interposed in a dielectric material. A dielectric layer 126 is deposited over the conductive layer 110 and the via openings 124 are formed in the dielectric layer 126 by conventional photolithography and etching processes. The dielectric layer 126 may or may not be made of the same material as the dielectric material in the conductive layer 110. The via openings 124 are substantially the same size and preferably arranged in a line having substantially equal pitch between each via opening and over the same conductive line. Each via opening 124 has a preferred height in a range of 0.7 to 1.4 um and has a preferred width in a range of 0.5 to 1.5 um. In another embodiment of the disclosure, each via opening has a preferred width of 1 um.

FIG. 1B is a cross-sectional view of the semiconductor device 100 after depositing a layer of conductive material 140. The conductive material 140 is deposited in the via openings 124 and over the dielectric layer 126 using a conventional deposition process, for example, a PVD process. Interconnect vias 128 are formed in the via openings 124 and a substantially uniform, flat layer of conductive material 140 is formed over the interconnect vias 128. The preferred conductive material is aluminum (Al), but other conductive materials may also be employed, such as copper (Cu) or gold (Au). The conductive material 140 deposited in the via openings 124 may or may not be the same conductive material used to fabricate the conductive line 120.

FIG. 1C illustrates the semiconductor device 100 after forming a probe pad 142 and depositing a passivation layer 144. The substantially uniform, flat layer of conductive material 140 is patterned and etched using conventional photolithographic and etching processes to form the probe pad 142 with a substantially flat surface 146 over the interconnect vias 128, i.e. a probe pad-on-via structure. In one embodiment of the semiconductor device, the probe pad 142 preferably has a square shape and has a width ranging from 4 to 14 um that is shorter than the width of a typical probe pad. In another embodiment, the probe pad 142 has a preferred width of 5 um. The probe pad 142 has a thickness in the range of 1.2 to 3 um. By a conventional deposition process, for example, a chemical vapor deposition (CVD) process, the passivation layer 144 is deposited on the probe pad 142 and on the dielectric layer 126.

FIG. 1D illustrates the semiconductor device 100 after exposing a portion of the probe pad surface 146. Using conventional photolithographic and etching processes to perform a pad opening process, a portion of the passivation layer 144 on the probe pad 142 is removed and a remaining portion of the passivation layer 144 partially overlaps edges of the probe pad 142 with an overlap dimension in the range of 0.5 to 2 um. In one embodiment of the semiconductor device, the exposed probe pad surface 146 has a width ranging from 2 to 10 um. In another embodiment, the exposed probe pad surface 146 has a preferred width of 4 um. The exposed probe pad surface 146 is subsequently cleaned to remove any residual passivation layer 144 that may be left behind after the pad opening process.

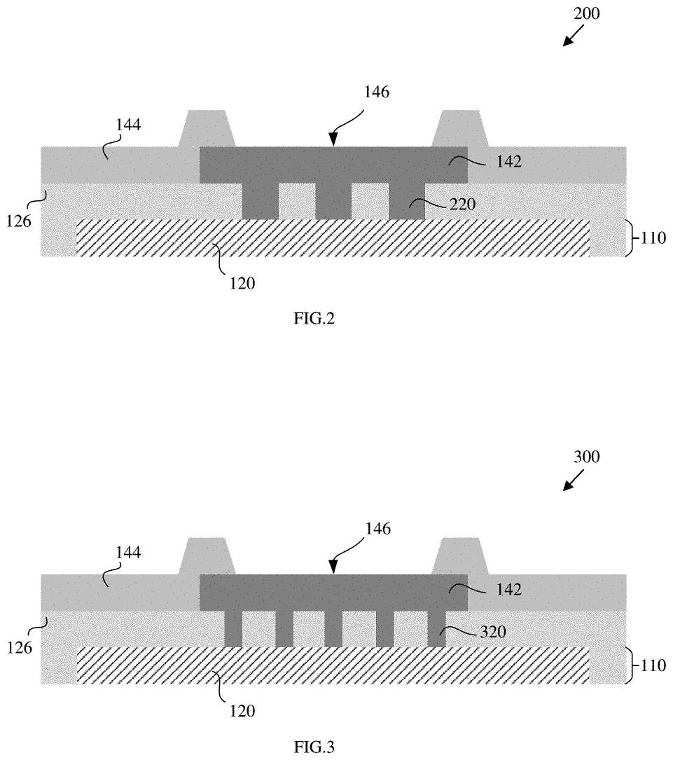

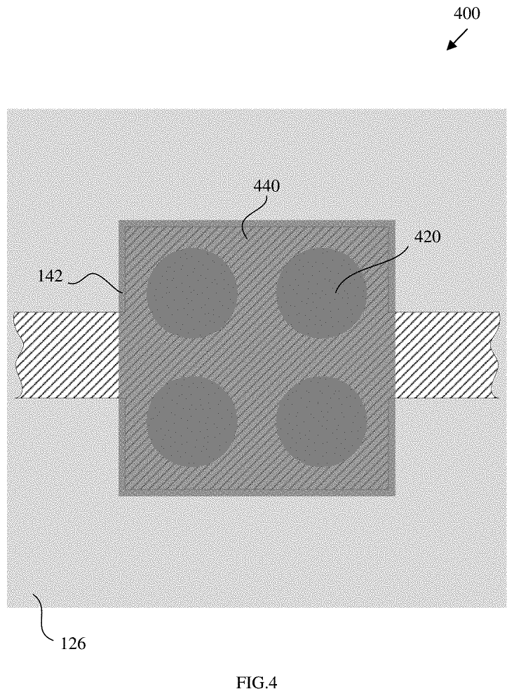

FIGS. 2 and 3 are cross-sectional views of semiconductor devices, according to other embodiments of the disclosure. As depicted, FIG. 2 illustrates a semiconductor device 200 including a probe pad 142 with three smaller interconnect vias 220 as compared with FIGS. 1A-1D. FIG. 3 illustrates another semiconductor device 300 including a probe pad 142 with five even smaller interconnect vias 320. The probe pads can be substantially the same size, but the dimensions and number of interconnect vias used with a particular probe pad can be different if the design of the semiconductor device has a preferred overall series resistance for the interconnect vias of that particular probe pad.

FIG. 4 is a top view of a semiconductor device 400, according to yet another preferred embodiment of the disclosure. The semiconductor device 400 includes a probe pad 142 over interconnect vias 420 that are placed in a two by two array. As depicted in FIG. 4, the interconnect vias 420 are placed over a conductive plate 440 connected by a conductive line. The array of interconnect vias 420 are substantially the same size and placed preferably in substantially equal pitch between each interconnect via and over the same conductive plate 440. The passivation layer 144 (not shown) partially overlaps edges of the probe pad 142 with an overlap dimension in the range of 0.5 to 2 um. In one embodiment of the disclosure, each interconnect vias 420 has a preferred width in the range of 0.5 to 1.5 um. In another embodiment, each interconnect via 420 has a preferred width of 1 um. The conductive plate 440 is preferably square-shaped and of similar size to the probe pad 142, although different shapes and sizes can also be employed. The interconnect vias 420 may also be arranged in other array configurations, such as a n×m matrix where n and m are integers of value 2 or more and wherein the values of n and m may be the same or different, for example, a three by two array or a three by three array.

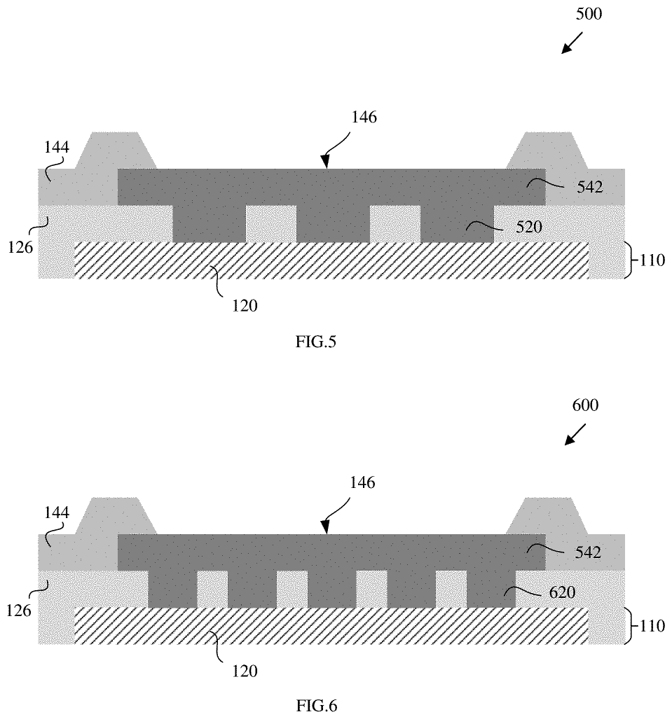

FIGS. 5 and 6 are cross-sectional views of semiconductor devices, according to alternative embodiments of the disclosure. FIGS. 5 and 6 illustrate semiconductor devices 500 and 600, respectively, including a larger probe pad 542 as compared with the probe pad 142 in FIGS. 1-3. In FIG. 5, the widths of interconnect vias 520 are substantially the same size and are greater than the widths of the interconnect vias 220 in FIG. 2. Similarly in FIG. 6, the widths of interconnect vias 620 are substantially the same size and are greater than the widths of the interconnect vias 320 in FIG. 3.

It is preferred to have up to 5 interconnect vias per probe pad, although greater quantities of interconnect vias may also be employed. Adoption of multiple interconnect vias are preferred to lower the overall series resistance of the interconnect vias. It should be appreciated that there are other possible combinations of varying interconnect via sizes and quantity that can be employed by those skilled in the art, and the combinations are not limited by the presented drawings in this disclosure.

In the above detailed description, a reduced-size probe pad-on-via structure with a substantially flat pad surface over a conductive layer is presented. The substantially flat pad surface is formed over a plurality of interconnect vias on a conductive layer. The smaller sized probe pads will enable placements of more probe pads within the chip area, without increasing the chip size for electrical testing purposes. In addition, the substantially flat pad surface will facilitate removal of the passivation layer when forming the exposed probe pad surface. It should also be appreciated that the embodiments of the disclosed probe pad-on-via structure and the method for fabricating such pad, as disclosed herein, are also applicable for a reduced-size bond pad structure.

The terms “top”, “bottom”, “over”, “under”, and the like in the description and in the claims, if any, are used for descriptive purposes and not necessarily for describing permanent relative positions. It is to be understood that the terms so used are interchangeable under appropriate circumstances such that the embodiments of the device described herein are, for example, capable of operation in other orientations than those illustrated or otherwise described herein.

Similarly, if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in one embodiment” herein do not necessarily all refer to the same embodiment.

In addition, unless otherwise indicated, all numbers expressing quantities, ratios, and numerical properties of materials, reaction conditions, and so forth used in the specification and claims are to be understood as being modified in all instances by the term “about”.

While several exemplary embodiments have been presented in the above detailed description of the device, it should be appreciated that number of variations exist. It should further be appreciated that the embodiments are only examples, and are not intended to limit the scope, applicability, dimensions, or configuration of the device in any way. Rather, the above detailed description will provide those skilled in the art with a convenient road map for implementing an exemplary embodiment of the device, it being understood that various changes may be made in the function and arrangement of elements and method of fabrication described in an exemplary embodiment without departing from the scope of this disclosure as set forth in the appended claims.

1. A semiconductor device comprising:
a conductive layer;
a plurality of interconnect vias over the conductive layer; and
a probe pad having a substantially flat surface over the plurality of interconnect vias, wherein the plurality of interconnect vias is arranged in an array configuration and has substantially equal pitch between each interconnect via.

2. The device of claim 1 wherein each one of the plurality of interconnect vias has a width in a range of 0.5 to 1.5 um.

3. The device of claim 1 wherein the plurality of interconnect vias has 5 or less interconnect vias.

4. (canceled)

5. The device of claim 1 wherein the conductive layer comprises a conductive line.

6. The device of claim 1 further comprising a passivation layer having overlap portions covering the probe pad and defining an exposed portion thereof, wherein the overlap portions have a width in a range of 0.5 to 2 um.

7. The device of claim 6 wherein the exposed portion of the probe pad has a width in a range of 2 to 10 um.

8. The device of claim 1 wherein the probe pad has a width in a range of 4 to 14 um.

9. The device of claim 1 wherein the probe pad comprises aluminum.

10. The device of claim 1 wherein the interconnect vias comprise aluminum.

11. (canceled)

12. A semiconductor device comprising:
at least one conductive plate;
an array of interconnect vias over the conductive plate, wherein the array of interconnect vias is arranged in a n×m matrix where n and m are integers of value 2 or more; and
a probe pad over the array of interconnect vias, wherein the probe pad and the array of interconnect vias are formed of a same conductive material.

13. The device of claim 12 wherein n and m have a same value.

14. (canceled)

15. A method of fabricating a pad structure comprising:
providing a conductive layer;
forming a dielectric layer over the conductive layer;
forming a plurality of via openings in the dielectric layer over the conductive layer;
depositing a conductive material in the plurality of via openings to form interconnect vias; and
forming a pad over the plurality of interconnect vias.

16. The method of claim 15 wherein forming the pad further comprises:
depositing a layer of conductive material over the plurality interconnect vias and selectively patterning the layer of conductive material to form the pad.

17. The method of claim 15 wherein the plurality of interconnect vias is arranged in a n×n matrix where n is an integer of value 2 or more.

18. The method of claim 15 wherein the pad has a width in a range of 4 to 14 um.

19. The method of claim 15 further comprising depositing a passivation layer with an opening having a width in a range of 2 to 10 um over the pad.

20. The method of claim 15 wherein the conductive material comprises aluminum.
